(19) United States
(12) Patent Application Publication
(10) Pub. No.: US 2026/0310186 A1
(43) Pub. Date: Oct. 8, 2026

(54) Substrate Processing System and Substrate Transfer Method

(71) Applicant: Tokyo Electron Limited, Tokyo (JP)

(72) Inventors: Yuki OKADA, Yamanashi (JP); Minoru NAGASAWA, Tokyo (JP)

(21) Appl. No.: 19/577,059

(22) Filed: Mar. 24, 2026

(30) Foreign Application Priority Data
Apr. 7, 2025 (JP) 2025-063191

(51) Int. Cl. G05B 19/418; H10P 72/00; B25J 11/00

(52) U.S. Cl. CPC G05B 19/41865; H10P 72/0454; B25J 11/0095; G05B 2219/25419

(57) ABSTRACT

A substrate processing system includes: a transfer module including a transfer device configured to transfer substrates; a plurality of processing modules configured to perform substrate processing on the substrates transferred by the transfer module; a substrate standby module configured to temporarily hold the substrates to be transferred to the plurality of processing modules; and a control device configured to create a schedule for the substrates based on the transfer module, the plurality of processing modules, and the substrate standby module, and transfer the substrates according to the schedule. The control device acquires information on availability or unavailability of the plurality of processing modules, and adjusts supply intervals of a plurality of substrates based on the number of available processing modules among the acquired plurality of processing modules.

### CROSS-REFERENCE TO RELATED APPLICATIONS

This application claims priority to Japanese Patent Application No. 2025-063191 filed on Apr. 7, 2025, the entire contents of which are incorporated herein by reference.

### TECHNICAL FIELD

The present disclosure relates to a substrate processing system and a substrate transfer method.

### BACKGROUND

Japanese Laid-open Patent Publication No. 2023-144823 discloses a substrate processing system including a plurality of transfer modules, a plurality of processing modules, and a control device that creates a schedule for transferring substrates based on a cycle time and performs control. In this type of substrate processing apparatus, when some of the plurality of processing modules become unavailable due to maintenance or errors, stagnation of substrates held by a transfer device of the transfer module occurs.

### SUMMARY

The present disclosure provides a technique capable of suppressing stagnation of substrates during transfer even when some of the plurality of processing modules are unavailable.

According to one aspect of the present disclosure, there is provided a substrate processing system including: a transfer module including a transfer device configured to transfer substrates; a plurality of processing modules configured to perform substrate processing on the substrates transferred by the transfer module; a substrate standby module configured to temporarily hold the substrates to be transferred to the plurality of processing modules; and a control device configured to create a schedule for the substrates based on the transfer module, the plurality of processing modules, and the substrate standby module, and control transfer of the substrates according to the schedule, wherein the control device acquires information on availability or unavailability of the plurality of processing modules, and adjusts supply intervals of a plurality of substrates based on the number of available processing modules among the acquired plurality of processing modules.

### BRIEF DESCRIPTION OF THE DRAWINGS

FIG. 1 is a plan view showing an overall configuration of a substrate processing system according to an embodiment.

FIG. 2 is a block diagram showing an example of a hardware configuration of a control device.

FIG. 3 is a table conceptually illustrating a schedule in the case of processing three substrates W by processing modules.

FIG. 4A is a diagram showing substrate supply intervals in the case where a processing module becomes unavailable in OR transfer using two processing modules.

FIG. 4B is a diagram showing substrate supply intervals in the case where a processing module becomes unavailable in OR transfer using three processing modules.

FIG. 4C is a diagram showing substrate supply intervals in the case of performing OR transfer using two processing modules among three processing modules according to a reference example.

FIG. 5A is a table conceptually illustrating a schedule in the case where a processing module becomes unavailable in OR transfer using processing modules.

FIG. 5B is a table conceptually illustrating a schedule in the case where a processing module becomes unavailable in OR transfer using processing modules according to a reference example.

FIG. 6 is a flowchart illustrating an example of processing flow of a substrate transfer method.

FIG. 7 is a diagram showing a first transfer pattern as another substrate transfer pattern.

FIG. 8 is a diagram showing a second transfer pattern as another substrate transfer pattern.

FIG. 9 is a diagram showing a third transfer pattern as another substrate transfer pattern.

FIG. 10 is a diagram showing a fourth transfer pattern as another substrate transfer pattern.

FIG. 11A is a first diagram illustrating a substrate transfer method according to a modification.

FIG. 11B is a diagram illustrating a substrate transfer method according to a reference example.

FIG. 11C is a second diagram illustrating a transfer method according to a modification.

### DETAILED DESCRIPTION

Hereinafter, embodiments for implementing the present disclosure will be described with reference to the accompanying drawings. Like reference numerals will be given to like or corresponding parts throughout the drawings, and redundant description thereof may be omitted.

### Overall configuration of substrate processing system 1

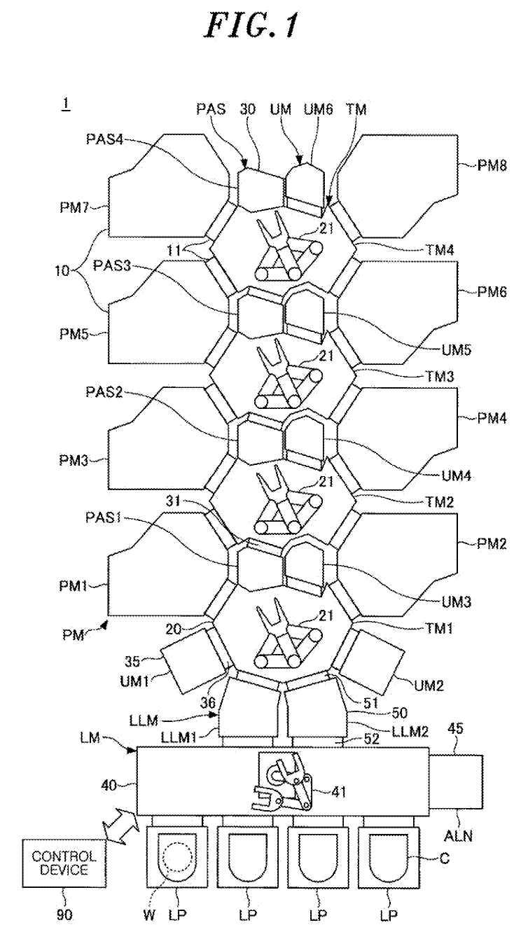

As shown in FIG. 1, a substrate processing system 1 according to an embodiment constitutes a multi-chamber type system including a plurality of processing modules PM for processing substrates W. Each processing module PM performs substrate processing such as film formation, etching, modification, cleaning, bonding, peeling, ashing, and the like on a substrate W transferred into the module. The substrate processing system 1 includes, in addition to the processing modules PM, a vacuum transfer module TM, pass modules PAS, utility modules UM, an atmospheric transfer module LM, load-lock modules LLM, a control device 90, and the like.

Eight processing modules PM according to the embodiment are installed with respect to the vacuum transfer module TM (hereinafter, the plurality of processing modules PM may be referred to as processing modules PM1 to PM8). Each of the processing modules PM1 to PM8 loads and unloads a substrate W into and from the vacuum transfer module TM, and performs substrate processing on the loaded substrate W. The number of processing modules PM of the substrate processing system 1 is not particularly limited. The plurality of processing modules PM may perform the same types of processing, or some or all of the processing modules PM may perform different types of processing. The substrate processing system 1 may be configured to perform plasma processing in some or all of the processing modules PM.

Each of the processing modules PM1 to PM8 includes a processing chamber 10 that accommodates a substrate W. A substrate support part (not shown) capable of placing thereon the substrate W transferred from the vacuum transfer device 21 of the vacuum transfer module TM is provided in the processing chamber 10.

Each of the processing modules PM1 to PM8 is connected to the vacuum transfer module TM via a gate valve 11. The gate valve 11 opens and closes the processing chamber 10 under the control of the control device 90. Each of the processing modules PM1 to PM8 allows the substrate W to be transferred into the processing chamber 10 by opening the gate valve 11, and allows the inside of the processing chamber 10 to be depressurized to a vacuum atmosphere by closing the gate valve 11.

The vacuum transfer module TM of the substrate processing system 1 includes a vacuum transfer container 20 connected to the respective processing modules PM1 to PM8, and a vacuum transfer device 21 provided in the vacuum transfer container 20 to actually transfer the substrate W. The vacuum transfer container 20 is formed in a polygonal shape in plan view to correspond to the connected modules (the processing modules PM, the pass/path modules PAS, the utility modules UM, and the load-lock modules LLM), and is airtightly sealed from the outside. The inside of the vacuum transfer container 20 is depressurized to a vacuum atmosphere by a depressurizing device (not shown).

The vacuum transfer device 21 moves in the vacuum transfer container 20 based on commands from the control device 90, and transfers the substrate W. The vacuum transfer device 21 includes two forks (a first fork and a second fork), and each fork can support the substrate W. Although FIG. 1 illustrates the vacuum transfer device 21 having two forks, the present disclosure is not limited thereto, and the vacuum transfer device 21 may have one fork or three or more forks.

The vacuum transfer module TM according to the embodiment connects multiple vacuum transfer containers 20, each having the vacuum transfer device 21, to each other via multiple pass modules PAS. Specifically, the vacuum transfer module TM includes a first vacuum transfer module TM1, a second vacuum transfer module TM2, a third vacuum transfer module TM3, and a fourth vacuum transfer module TM4 in that order in a direction distant from the atmospheric transfer module LM (the load-lock modules LLMs) side.

The first vacuum transfer module TM1 is connected to two processing modules PM1 and PM2, one pass module PAS1, three utility modules UM1 to UM3, and two load-lock modules LLM. The second vacuum transfer module TM2 is connected to four processing modules PM1 to PM4, two pass modules PAS1 and PAS2, and one utility module UM4. The third vacuum transfer module TM3 is connected to four processing modules PM3 to PM6, two pass modules PAS2 and PAS3, and one utility module UM5. The fourth vacuum transfer module TM4 is connected to four processing modules PM5 to PM8, two pass modules PAS3 and PAS4, and one utility module UM6. However, the substrate processing system 1 is not limited to such a configuration, and the number and arrangement of the vacuum transfer modules TM may be arbitrarily designed. For example, the substrate processing system may include the vacuum transfer module TM having one vacuum transfer container 20 and one vacuum transfer device 21.

The vacuum transfer module TM can transfer the substrate W to a target module by the vacuum transfer device 21. For example, the substrate processing system 1 can transfer the substrate W from the load-lock module LLM1 to a target processing module PM, perform substrate processing in the target processing module PM, and then return the substrate W from the processing module PM to the load-lock module LLM. Alternatively, the vacuum transfer module TM may transfer the substrate W between two processing modules PM. For example, the substrate processing system 1 can transfer the substrate W processed in the processing module PM1 to the processing module PM3 for further processing. In this case, the vacuum transfer module TM transfers the substrate W from the processing module PM1 to the pass module PAS1 by the vacuum transfer device 21 of the first vacuum transfer module TM1, and then transfers the substrate W from the pass module PAS1 to the processing module PM3 by the vacuum transfer device 21 of the second vacuum transfer module TM2. Alternatively, the vacuum transfer module TM may be configured such that the vacuum transfer device 21 of the second vacuum transfer module TM2 takes out the substrate W from the processing module PM1 and transfers the substrate W to the processing module PM3.

The pass module PAS allows the substrate W to be transferred between adjacent vacuum transfer modules TM, and constitutes a substrate standby module that temporarily holds the substrate W to be transferred. The number of pass modules PAS provided between adjacent vacuum transfer modules TM is not limited to one, and may be two or more.

Each of the pass modules PAS1 to PAS4 includes a pass container 30 connected to the vacuum transfer module TM, and a substrate support part (not shown) capable of supporting a substrate W in the pass container 30. Further, the pass module PAS includes a gate 31 capable of opening and closing the pass container 30 on one of the two vacuum transfer modules TM sides between which the pass module PAS is interposed. Further, the pass module PAS may include the gates 31 on both of the two vacuum transfer modules TM sides, or may include no gates on either side.

The plurality of utility modules UM are attached to the vacuum transfer module TM, and have a function of making the substrates W stand by and performing processing separately from the processing modules PM. For example, the utility module UM has a function of adjusting (heating or cooling) the temperature of the substrate W before the substrate W is processed by the processing module PM. Alternatively, the utility module UM may perform processing such as temperature adjustment on the substrate W after the substrate W is processed by the processing module PM. The utility module UM may have only a function of simply making the substrate W stand by. In other words, the utility module UM may function as a processing module that performs substrate processing on the substrate W, and may function as a substrate standby module that makes the substrate W stand by.

For example, the utility module UM1 connected to the first vacuum transfer module TM1 temporarily holds the substrate W transferred from the load-lock module LLM1. The utility module UM2 temporarily holds the substrate W to be transferred to the load-lock module LLM2. Further, the utility modules UM3 to UM6 adjust the temperature while temporarily holding the substrates W before or after the processing in the processing modules PM1 to PM8. The number of utility modules UM is not limited to the illustrated example, and may be one to five, or seven or more. The utility modules UM may not be installed in the substrate processing system 1.

The atmospheric transfer module LM of the substrate processing system 1 transfers the substrate W while maintaining the inside thereof in an atmospheric pressure atmosphere. The atmospheric transfer module LM includes an atmospheric transfer container 40 connected to the load-lock modules LLM, and an atmospheric transfer device 41 provided in the atmospheric transfer container 40 to transfer the substrates W. Further, the atmospheric transfer module LM includes an aligner device ALN for aligning the substrate W on one lateral side of the atmospheric transfer container 40. The atmospheric transfer module LM may include a fan filter unit (FFU) that supplies clean air in a downflow manner in the atmospheric transfer container 40.

The atmospheric transfer module LM may be, e.g., an equipment front end module (EFEM). In this case, a plurality of load ports LP on which storage containers C containing multiple substrates W or empty storage containers C are set are provided on one side of the atmospheric transfer module LM. The storage container C may be, e.g., a front opening unified pod (FOUP).

The atmospheric transfer device 41 transfers the substrate W while moving in the atmospheric transfer container 40 under the control of the control device 90, and loads and unloads the substrate W into and from each load-lock module LLM, the storage container C, the aligner device ALN, and the like. The atmospheric transfer device 41 may adopt substantially the same configuration as that of the vacuum transfer device 21.

The load-lock modules LLM, which are provided between the vacuum transfer module TM and the atmospheric transfer module LM, temporarily hold the substrates W and allow the transfer of the substrates W between both modules. In the embodiment, two load-lock modules LLM1 and LLM2 are provided along the longitudinal direction of the atmospheric transfer module LM. However, the number of load-lock modules LLM is not particularly limited, and may be one or three or more.

Each load-lock module LLM includes a container body 50 that accommodates substrates W. Further, each load-lock module LLM further includes a gate valve 51 between the container body 50 and the vacuum transfer container 20 of the first vacuum transfer module TM1, and a door valve 52 between the container body 50 and the atmospheric transfer container 40 of the atmospheric transfer module LM. Each load-lock module LLM communicates with the atmospheric transfer module LM by opening the door valve 52 under an atmospheric pressure atmosphere. Each load-lock module LLM communicates with the first vacuum transfer module TM1 by opening the gate valve 51 under a vacuum atmosphere.

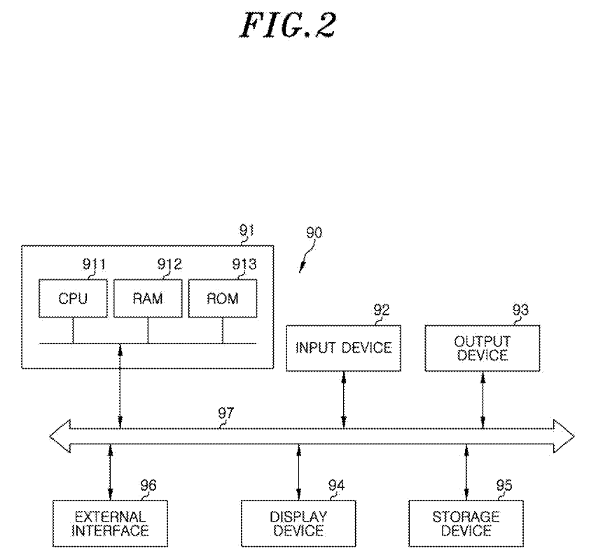

The substrate processing system 1 configured as described above performs transfer processing and substrate processing for the substrate W by controlling the above components using the control device 90. FIG. 2 is a block diagram showing an example of a hardware configuration of the control device 90. As shown in FIG. 2, the control device 90 of the substrate processing system 1 includes a main controller 91, an input device 92, an output device 93, a display device 94, a storage device 95, an external interface 96, and a bus 97 that connects these components to each other. The input device 92 includes a keyboard, a mouse, a touch panel, or the like. The output device 93 includes a printer or the like. The display device 94 includes a display (including a touch panel) or the like.

The main controller 91 includes a processor 911 such as a central processing unit (CPU), a random access memory (RAM) 912, and a read only memory (ROM) 913. The storage device 95 includes a storage medium capable of reading information, such as a hard disk drive (HDD), and stores information such as programs required for control, and recipes for processing substrates W. The processor 911 executes programs stored in the ROM 913 or the storage device 95 using the RAM 912 as a work area, so that the substrate processing system 1 performs various processes.

The control device 90 controls individual components of the substrate processing system 1 to sequentially transfer a plurality of substrates W from the atmospheric transfer module LM to the vacuum transfer module TM, and executes substrate processing in each processing module PM of the vacuum transfer module TM. In this case, the substrate processing system 1 needs to be controlled such that the plurality of substrates W are not simultaneously held on each fork of the vacuum transfer device 21. Therefore, before the transfer processing and the substrate processing for each substrate W are performed, the control device 90 creates a schedule and executes the transfer processing and the substrate processing according to the created schedule.

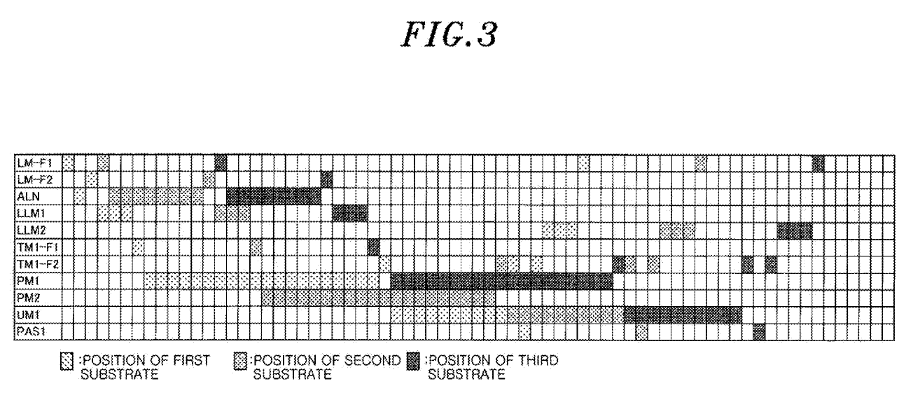

FIG. 3 is a table conceptually illustrating a schedule in the case of processing three substrates W using the processing modules PM1 and PM2. In the table shown in FIG. 3, the horizontal direction represents a time axis, and cells divided by grid lines have appropriate time widths. However, the time width of each cell arranged in the horizontal direction is not always constant, but is merely conceptually divided to make the time width easier to understand. In other words, while the period of one cell divided in the horizontal direction may be 10 seconds, the period of an adjacent cell may be 20 seconds.

The items in the vertical direction in the table of FIG. 3 indicate, by abbreviations, the components where the substrate W is located (stays). Specifically, LM-F1 is the first fork of the atmospheric transfer device 41 of the atmospheric transfer module LM, and LM-F2 is the second fork of the atmospheric transfer device 41 of the atmospheric transfer module LM. ALN is the aligner device. LLM1 and LLM2 are the load-lock modules. TM-F1 is the first fork of the vacuum transfer device 21 of the first vacuum transfer module TM1, and TM-F2 is the second fork of the vacuum transfer device 21 of the first vacuum transfer module TM1. PM1 and PM2 are the processing modules. UM1 is the utility module UM. PAS1 is the pass module. In other words, in FIG. 3, in order to facilitate understanding of the present disclosure, a schedule in the case of transferring three substrates W to the processing modules PM1 and PM2 by the first vacuum transfer module TM1 is exemplified.

In other words, “schedule” is a plan for positions of a plurality of substrates W over time in the substrate processing system 1. The substrate processing system 1 basically performs the transfer processing and the substrate processing for the substrate W according to the schedule. However, the substrate processing system 1 can correct or change the schedule according to the module states (delay, error, or the like). By setting and controlling the position of each substrate W in the schedule, the control device 90 can prevent the substrates W from overlapping on each fork (the first fork and the second fork) of the vacuum transfer device 21 during the transfer processing.

Hereinafter, the example of FIG. 3 will be described. A first substrate W is first held by the first fork of the atmospheric transfer device 41 and transferred to the aligner device ALN. After the alignment at the aligner device ALN, the first substrate W is held by the second fork of the atmospheric transfer device 41 and transferred to the load-lock module LLM1. Thereafter, the first substrate W is held by the first fork of the vacuum transfer device 21 and transferred to the processing module PM1. The processing module PM1 performs the substrate processing on the first substrate W. After the substrate processing, the first substrate W is held by the second fork of the vacuum transfer device 21 and transferred to the utility module UM1, and the temperature is adjusted in the utility module UM1. The first substrate W is taken out from the utility module UM1 by the second fork of the vacuum transfer device 21, made to temporarily stand by in the pass module PAS1, and held again by the second fork of the vacuum transfer device 21 and transferred to the load-lock module LLM2. Finally, the first substrate W is held by the first fork of the atmospheric transfer device 41 and stored in the storage container C.

A second substrate W is held by the first fork of the atmospheric transfer device 41 and transferred to the aligner device ALN at the timing when the first substrate W is transferred to the load-lock module LLM (including before and after the transfer). After the alignment in the aligner device ALN, the second substrate W temporarily stands by in the aligner device ALN, and then is held by the second fork of the atmospheric transfer device 41 and transferred to the load-lock module LLM1. Thereafter, the second substrate W is held by the first fork of the vacuum transfer device 21 and transferred to the processing module PM2. The processing module PM2 performs the substrate processing on the second substrate W. During the substrate processing of the second substrate W, the first substrate W that has been processed in the processing module PM1 is taken out.

After the substrate processing, the second substrate W is held by the second fork of the vacuum transfer device 21 and transferred to the utility module UM1, and the temperature is adjusted in the utility module UM1. The second substrate W is taken out from the utility module UM1 by the second fork of the vacuum transfer device 21, made to temporarily stand by in the pass module PAS1, and held again by the second fork of the vacuum transfer device 21 and transferred to the load-lock module LLM2. Finally, the second substrate W is held by the first fork of the atmospheric transfer device 41 and stored in the storage container C.

A third substrate W is held by the first fork of the atmospheric transfer device 41 and transferred to the aligner device ALN at the timing when the second substrate W is transferred to the load-lock module LLM (including before and after the transfer). After the alignment in the aligner device ALN, the third substrate W temporarily stands by in the aligner device ALN, and then is held by the second fork of the atmospheric transfer device 41 and transferred to the load-lock module LLM1. Thereafter, the third substrate W is held by the first fork of the vacuum transfer device 21 and transferred to the processing module PM1. The transfer timing of the third substrate W is the timing at which the first substrate W is taken out from the processing module PM1, which makes the exchange of the first substrate W and the third substrate W possible. The processing module PM1 performs the substrate processing on the third substrate W. During the substrate processing of the third substrate W, the second substrate W that has been processed in the processing module PM2 is taken out.

After the substrate processing, the third substrate W is also held by the second fork of the vacuum transfer device 21 and transferred to the utility module UM1, and the temperature is adjusted in the utility module UM1. The third substrate W is taken out from the utility module UM1 by the second fork of the vacuum transfer device 21, made to temporarily stand by in the pass module PAS1, and held again by the second fork of the vacuum transfer device 21 and transferred to the load-lock module LLM2. Finally, the third substrate W is held by the first fork of the atmospheric transfer device 41 and stored in the storage container C.

As described above, the control device 90 can appropriately control the position of each substrate W in the substrate processing system 1 by associating each time in the schedule with the position of each substrate W, thereby suppressing congestion of the substrates W during the transfer processing. In particular, by setting the position of the substrate W for each fork of the vacuum transfer device 21 and for each fork of the atmospheric transfer device 41, the control device 90 can easily recognize substrates W that are being held by the forks.

The schedule of FIG. 3 is an example of the substrate processing system 1 in which the processing module PM1 and the processing module PM2 connected to the first vacuum transfer module TM1 perform the same substrate processing. In other words, the control device 90 of the substrate processing system 1 controls OR transfer in which substrates are selectively transferred to the processing modules PM1 and PM2 that perform the same substrate processing. By performing the OR transfer and performing the substrate processing in each of the processing modules PM1 and PM2, the substrate processing system 1 can improve the efficiency of processing of each substrate W.

In the operation of the substrate processing system 1, some of the plurality of processing modules PM may become unavailable. For example, the processing module PM becomes unavailable when an error occurs in the processing module PM, when maintenance is performed in the processing module PM, and when processing (for example, cleaning) other than the substrate processing is performed in the processing module PM. In the substrate processing system 1 according to the embodiment, when the unavailable processing module PM is recognized, the processing is executed to reset supply intervals of a plurality of substrates W based on the number of processing modules PM capable of transferring substrates W.

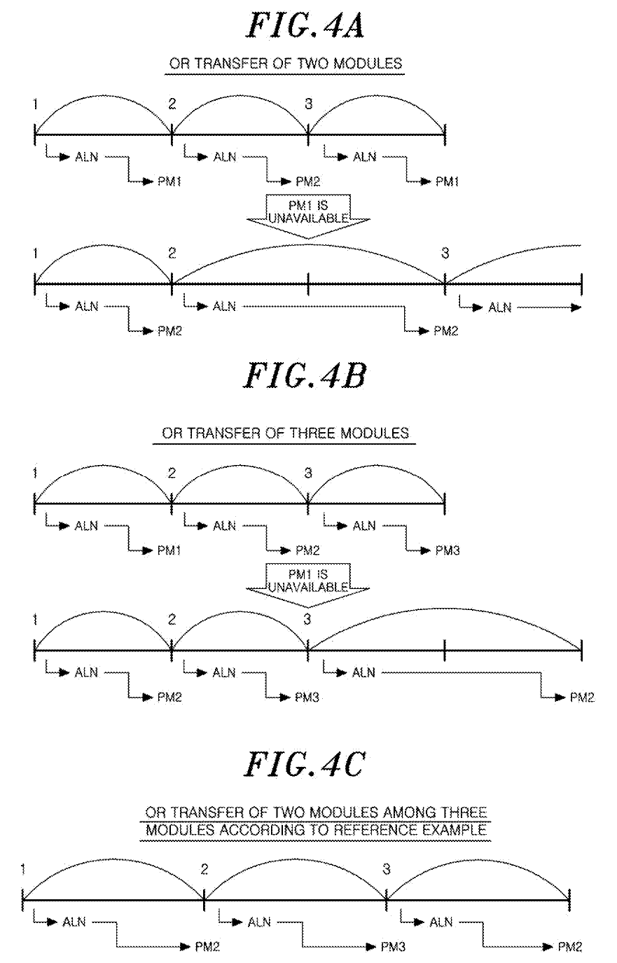

FIG. 4A is a diagram showing supply intervals of substrates W when the processing module PM1 becomes unavailable in the OR transfer using two processing modules PM1 and PM2. FIG. 4B is a diagram showing supply intervals of substrates W when the processing module PM1 becomes unavailable in the OR transfer using three processing modules PM1 to PM3. FIG. 4C is a diagram showing supply intervals of substrates W in the OR transfer using two processing modules PM2 and PM3 among three processing modules PM1 to PM3 according to a reference example.

In the OR transfer using two processing modules PM1 and PM2, when both processing modules PM are available, as shown in the upper diagram of FIG. 4A, a first substrate W is transferred to the processing module PM1 and a second substrate W is transferred to the processing module PM2. A third substrate W is transferred to the processing module PM1 where the substrate processing of the first substrate W has been completed, and a fourth substrate W is transferred to the processing module PM2 where the substrate processing of the second substrate W has been completed. By repeating the same procedure, each substrate W can be processed efficiently.

However, when one of the two processing modules PM1 and PM2 (for example, the processing module PM1) becomes unavailable, the substrate processing is performed on each substrate W using only one processing module PM2. In this case, as shown in the lower diagram of FIG. 4A, the control device 90 transfers the first substrate W in a normal manner, and performs adjustment for increasing the supply intervals of the second substrate W. The supply intervals of third and subsequent substrates W are also increased in the same manner. For example, the supply intervals of the second substrate W are increased up to the supply timing of the third substrate W set in the schedule. As a result, even if one processing module PM1 becomes unavailable in the OR transfer using two processing modules PM1 and PM2 and the supply intervals of the second and subsequent substrates W are increased, it is possible to avoid the shift in the supply timing of the previously created schedule.

Here, in this specification, “supply timing” refers to timing at which the control device 90 transfers the substrate W into a target processing module PM set by the control device 90. In addition, “supply intervals of substrates W” refers to a period between a current substrate W and a next substrate W at the time of transferring the substrates from the load-lock modules LLM to the vacuum transfer module TM. However, when the timing of sequentially taking out a plurality of substrates W from the storage container C is associated with the timing of transferring the substrates from the load-lock module LLM to the vacuum transfer module TM, the supply intervals of substrates W may be a period in which a plurality of substrates W are taken out from the storage container C.

In the case of increasing the supply intervals of substrates W, in the substrate processing system 1 according to the embodiment, the time in which the substrates W stand by (stay) in the aligner device ALN is increased, and the previously created schedule for the time in which the substrates W are held in the vacuum transfer device 21 is maintained. As a result, it is possible to suppress a state in which the substrates W are held (stagnate) in the vacuum transfer device 21 of the vacuum transfer module TM and to maintain substantially the same temperature (thermal history or the like) for the substrates W.

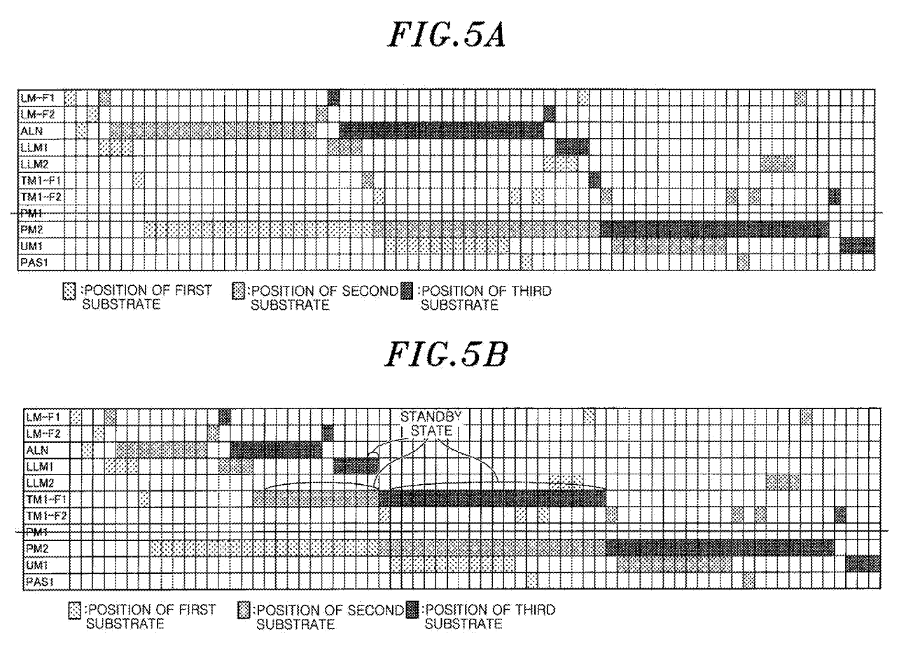

FIG. 5A is a table conceptually illustrating a schedule in the case where the processing module PM1 becomes unavailable in the OR transfer using the processing modules PM1 and PM2. FIG. 5B is a table conceptually illustrating a schedule in the case where the processing module PM1 becomes unavailable in the OR transfer using the processing modules PM1 and PM2 according to a reference example. In FIGS. 5A and 5B, the processing module PM1 that has become unavailable is indicated by cancellation lines.

First, in the schedule according to the reference example, when the processing module PM1 becomes unavailable, it is determined that all the substrates W (the first to third substrates and subsequent substrates) are to be processed in the processing module PM2. This is because, in the OR transfer using two processing modules PM, when one processing module PM becomes unavailable, it is possible to handle processing using only the other processing module PM.

However, the schedule according to the reference example shown in FIG. 5B illustrates an example in which the substrates W are sequentially supplied to the vacuum transfer module TM without particularly adjusting the supply intervals of the substrates W. Specifically, in the substrate transfer method according to the reference example, the first substrate W, the second substrate W, and the third substrate W are taken out from the storage container C at the same supply intervals as the supply intervals of the substrates W described with reference to FIG. 3.

As described above, also in the schedule according to the reference example, all the substrates W (the first substrate W, the second substrate W, and the third substrate W) are processed only in the processing module PM2 that is the target of the OR transfer. Therefore, for example, the second substrate W is transferred to the first vacuum transfer module TM1 and stands by while being held on the first fork of the vacuum transfer device 21 until the substrate processing of the first substrate W in the processing module PM2 is completed. When the substrate processing of the first substrate W is completed, the first substrate W is unloaded and the second substrate W is loaded, thereby starting the substrate processing of the second substrate W in the processing module PM2.

Similarly, the third substrate W temporarily stands by in the load-lock module LLM1 during the substrate processing of the first substrate W. The third substrate W is transferred to the first vacuum transfer module TM1, and stands by while being held on the first fork of the vacuum transfer device 21 until the substrate processing of the second substrate W in the processing module PM2 is completed. When the substrate processing of the second substrate W is completed, the second substrate W is unloaded and the third substrate W is loaded, thereby starting the substrate processing of the third substrate W in the processing module PM2.

As described above, in the substrate transfer method according to the reference example, the standby period of the first substrate W, the standby period of the second substrate W, and the standby period of the third substrate W in the first vacuum transfer module TM1 are different from each other. As a result, the thermal histories (the temperature of the first substrate W, the temperature of the second substrate W, and the temperature of the third substrate W) of the substrates W become different from each other, thereby affecting the uniformity of the substrate processing in the processing module PM2.

Therefore, in the substrate transfer method according to the embodiment shown in FIG. 5A, in response to the unavailability of the processing module PM1, the timing at which the substrates W are taken out from the storage container C is adjusted, and the substrates W stand by in the aligner device ALN to adjust the supply intervals of the substrates W. Specifically, the first substrate W is transferred to the processing module PM2 in the same manner as in the schedule of FIG. 3, and the substrate processing is performed in the processing module PM2.

The second substrate W is taken out from the storage container C and transferred to the aligner device ALN at the same timing as in the schedule of FIG. 3. Then, the second substrate W stands by in the aligner device ALN according to the period of substrate processing of the first substrate W in the processing module PM2. In other words, in the substrate transfer method according to the embodiment, the supply intervals of substrates W are adjusted in the aligner device ALN provided on the atmospheric transfer module LM side. The aligner device ALN may perform the alignment of the substrate W when the substrate W stands by.

The end timing (the timing at which the second substrate W is transferred from the load-lock module LLM into the first vacuum transfer module TM1) of the supply intervals of the second substrate W standing by in the aligner device ALN is set to be close to the end of the substrate processing of the processing module PM2. The control device 90 controls the atmospheric transfer device 41 and the vacuum transfer device 21, based on the end timing, to transfer the second substrate to the load-lock module LLM1, and to load the second substrate W from the load-lock module LLM1 into the first vacuum transfer module TM1. As a result, the standby period of the second substrate W in the load-lock module LLM1 and the first vacuum transfer module TM1 becomes the same as the standby period of the first substrate W. The substrate processing of the second substrate W is performed in the processing module PM2.

The third substrate W is taken out from the storage container C by the atmospheric transfer device 41 after the second substrate W is taken out from the aligner device ALN, transferred to the aligner device ALN, and stand by in the aligner device ALN according to the substrate processing period in the processing module PM2. The end timing of the supply intervals of the third substrate W standing by in the aligner device ALN is also set to be close to the end of the substrate processing of the processing module PM2. The control device 90 controls the atmospheric transfer device 41 and the vacuum transfer device 21, based on the end timing, to transfer the third substrate W to the load-lock module LLM1, and to load the third substrate W from the load-lock module LLM1 into the first vacuum transfer module TM1. The standby period of the third substrate W in the load-lock module LLM1 and the first vacuum transfer module TM1 becomes the same as the standby periods of the first and second substrates W. The substrate processing of the third substrate W is performed in the processing module PM2. The fourth and subsequent substrates W may also be transferred at the same supply intervals as those of the third substrate W.

As described above, in the substrate transfer method according to the embodiment, by adjusting the supply intervals of the second and subsequent substrates W in the aligner device ALN on the atmospheric side, the standby periods of the substrates W in a vacuum atmosphere can become the same, thereby making the thermal histories of the substrates W uniform. The configuration in which the substrates W stand by on the atmospheric side is not limited to the aligner device ALN. For example, the atmospheric transfer module LM may include a substrate stocker module for making one or more substrates W stand by in or around the atmospheric transfer container 40.

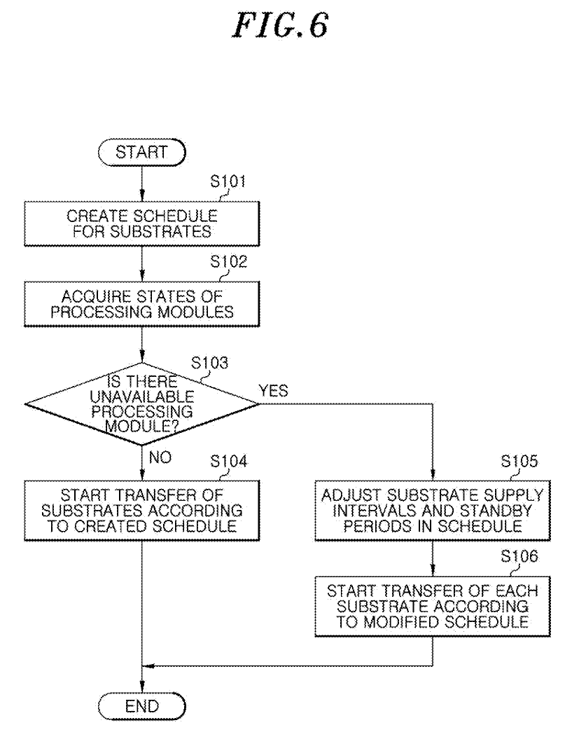

The substrate processing system 1 according to the embodiment is basically configured as described above. Hereinafter, the substrate transfer method will be described with reference to FIG. 6. FIG. 6 is a flowchart illustrating an example of processing flow of the substrate transfer method.

The control device 90 of the substrate processing system 1 sequentially executes the processing flow of steps S101 to S106 shown in FIG. 6 in the substrate transfer method.

The control device 90 creates a schedule for transfer processing and substrate processing of each substrate W according to recipes for the substrate processing in each processing module PM (step S101). In this case, the schedule prioritizes the efficiency of the transfer processing and the substrate processing, so that the substrates W in the storage container C are sequentially taken out and transferred to the vacuum transfer module TM and the substrate processing is performed in each processing module PM.

Next, the control device 90 acquires the states of the processing modules PM that perform the substrate processing on the substrates W (step S102). The states of the processing modules PM include information on availability or unavailability of the processing modules PM. For example, the control device 90 acquires information, such as occurrence of errors in the processing modules PM or maintenance of the processing modules PM, through internal processing. Alternatively, the control device 90 may acquire information on various sensors provided at the processing modules PM, and set availability or unavailability of the processing modules PM based on the information.

Then, the control device 90 determines whether there is any processing module PM that is unavailable among the plurality of processing modules PM that are targets of the OR transfer (step S103). When the processing module PM for serial transfer rather than for OR transfer is unavailable, the substrate processing cannot be performed in the processing module PM. Therefore, it is preferable to stop the operation of the substrate processing system 1 until the processing module PM that is the target of serial transfer becomes available.

If there is no unavailable processing module PM (step S103: NO), the process proceeds to step S104. In step S104, the control device 90 starts the transfer of each substrate W according to the created schedule. As a result, the substrate processing system 1 can efficiently transfer the substrates W and perform the substrate processing in each processing module PM.

On the other hand, if there is an unavailable processing module PM (step S103: YES), the process proceeds to step S105. In step S105, the control device 90 adjusts the supply intervals of the substrates W in the schedule and the standby periods of the substrates W standing by in the aligner device ALN based on the number of available processing modules PM. As a result, the control device 90 can modify the schedule created in step S101 according to the available processing modules PM.

Then, the control device 90 starts the transfer of each substrate W according to the modified schedule (step S106). As a result, the substrate processing system 1 can load the substrates W of which supply intervals have been appropriately adjusted into the available processing modules PM, thereby improving the uniformity of the substrate processing.

As described above, in the substrate processing system 1 and the substrate transfer method according to the embodiment, even if some of the plurality of processing modules PM become unavailable, it is possible to suppress stagnation of the substrates W during transfer by appropriately adjusting the supply intervals of the substrates W.

The substrate processing system 1 and the substrate processing method according to the embodiment are not limited to the above-described embodiment, and various modifications may be made. For example, the substrate waiting module for making the substrates W wait is not limited to the atmospheric transfer module LM (the aligner device ALN) side. For example, the utility module UM of the vacuum transfer module TM may serve as the substrate standby module for making the substrates W stand by. In this case, it is preferable that the utility module UM performs temperature adjustment control such that the temperature of the substrates W that are standing by is maintained at a substantially constant temperature (target temperature).

For example, in the substrate processing system 1, three or more processing modules PM may be used targets for OR transfer. In the case of performing the OR transfer using three processing modules PM1 to PM3 in the substrate processing system 1, the control device 90 creates a schedule in which the first substrate W, the second substrate W, and the third substrate W are transferred in that order, as shown in the upper diagram of FIG. 4B. Then, if the processing module PM1 becomes unavailable, the substrate processing of each substrate W is performed using two processing modules PM2 and PM3 among the three processing modules PM1 to PM3.

In this case, it is conceivable to divide the supply intervals of the substrates W into equal periods, as in the substrate transfer method according to the reference example shown in FIG. 4C. However, when the supply intervals of the substrates W are evenly divided, the supply timing of the substrates W is shifted from the supply timing expected in the previously created schedule. In that case, for example, when the system returns to the created schedule after the unavailable processing module PM1 becomes available, the supply timing may be shifted from the supply timing of the created schedule. When the supply timing is shifted from the schedule, stagnation may occur during the transfer of the substrates W.

Therefore, as shown in the lower diagram of FIG. 4B, the control device 90 is configured to change the supply intervals of the substrates W to match the supply timing of the substrates W expected in the previously created schedule. Specifically, when the first substrate W is processed in the processing module PM2 and the second substrate W is processed in the processing module PM3, the control device 90 increases the supply intervals of the third substrate W. In this case, the control device 90 adjusts the supply intervals of the third substrate W to be longer by the amount corresponding to the supply timing expected in the schedule. In other words, the supply intervals of the third substrate W is increased discretely for each supply timing of the substrates W in the schedule, so that the third substrate W stands by in the aligner device ALN. As a result, the supply timing at which the third substrate W is taken out from the aligner device ALN can be matched with the supply timing of the substrates W expected in the schedule.

In summary, when the supply intervals of the substrates W are adjusted, it is preferable to adjust the supply intervals of the substrates W based on the number of processing modules PM that are targets of the OR transfer and the number of available processing modules PM. As a result, for example, even when an unavailable processing module PM becomes available during the operation of the substrate processing system 1, it is possible to smoothly return to the supply intervals of the substrates W in the schedule. Further, even when some processing modules PM become unavailable during the operation of the substrate processing system 1, the substrates W can be transferred without being shifted from the expected supply timing of the substrates W.

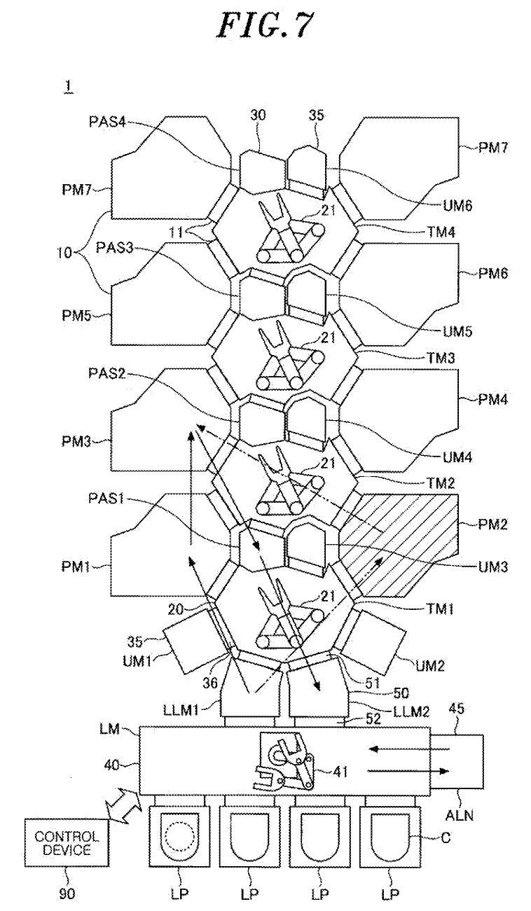

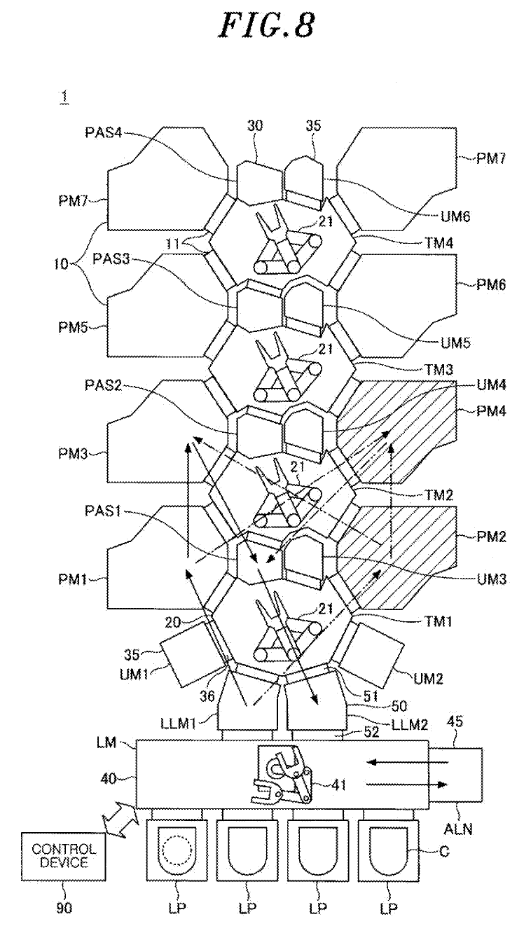

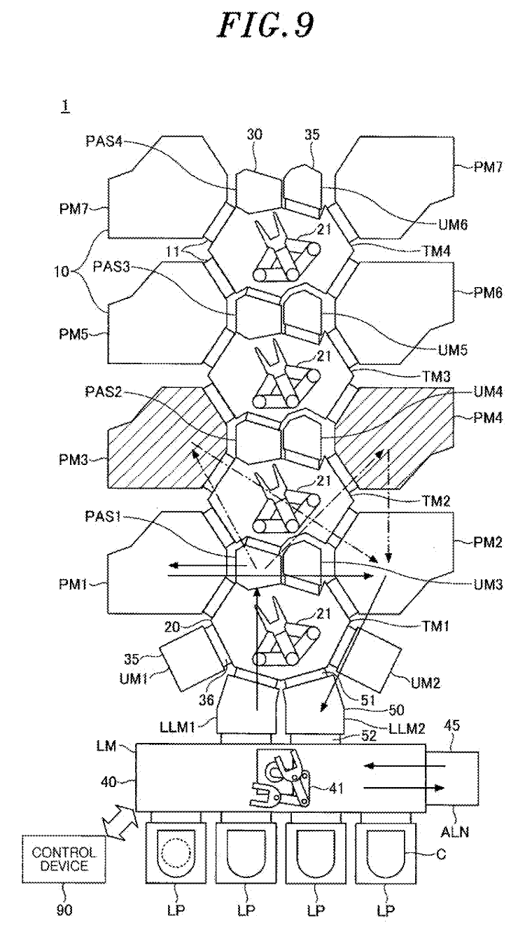

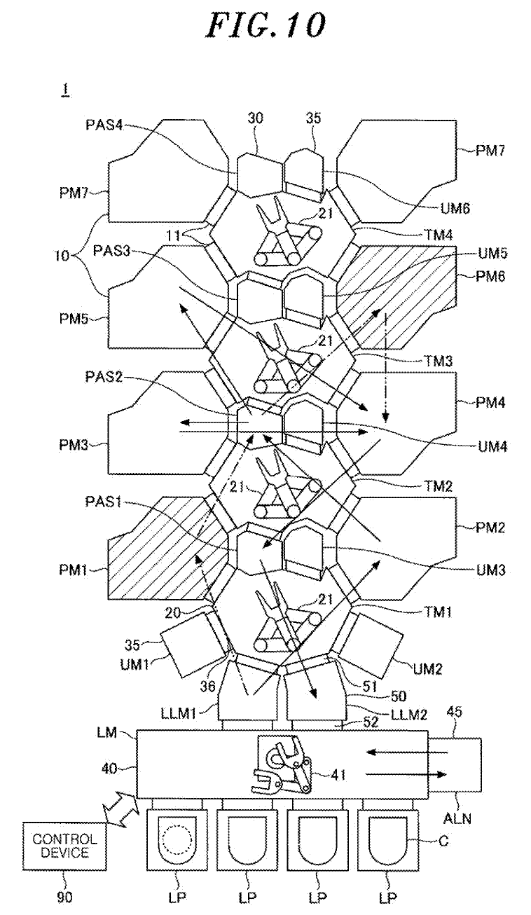

Hereinafter, several examples of other transfer patterns of the substrates W in the substrate processing system 1 will be illustrated with reference to FIGS. 7 to 10. FIG. 7 is a diagram showing a first transfer pattern as another transfer pattern of the substrates W. FIG. 8 is a diagram showing a second transfer pattern as another transfer pattern of the substrates W. FIG. 9 is a diagram showing a third transfer pattern as another transfer pattern of the substrates W. FIG. 10 is a diagram showing a fourth transfer pattern as another transfer pattern of the substrates W. In FIGS. 7 to 10, processing modules PM that are unavailable are distinguished from available processing modules PM by hatching.

In the first transfer pattern shown in FIG. 7, the OR transfer of the substrate W from the load-lock module LLM1 to the processing module PM1 or the processing module PM2 is performed. Further, the first transfer pattern adopts a route in which the substrates W are serially transferred to the processing module PM3, and then returned to the load-lock module LLM2 via the pass module PAS1. In the first transfer pattern, for example, when the processing module PM2 becomes unavailable, the route from the load-lock module LLM to the processing module PM2 and the route from the processing module PM2 to the processing module PM3 are eliminated (see dashed double-dotted lines in FIG. 7).

Then, the substrate transfer method is changed to follow the transfer pattern in which all the substrates W are transferred to the processing module PM1 for OR transfer. The processing module PM3 and the pass module PAS1 are originally included in a route through which all the substrates W are transferred. Therefore, the two processing modules PM for OR transfer may be changed to one processing module PM. Accordingly, as shown in FIG. 4A, the control device 90 performs control to change the two processing modules PM to one processing module PM, thereby changing the supply intervals of the substrates W.

In the second transfer pattern shown in FIG. 8, the OR transfer of substrates W from the load-lock module LLM1 to the processing module PM1 or the processing module PM2 is performed. In next processing, the OR transfer to the processing module PM3 or the processing module PM4 is performed. The second transfer pattern adopts a route in which the substrates W are returned to the load-lock module LLM2 via the pass module PAS1 after the substrate processing in the processing modules PM3 and PM4. Since the second transfer pattern has two processing modules for OR transfer, it is possible to cope with the case where the processing module PM becomes unavailable in each OR transfer. FIG. 8 illustrates an example in which the processing modules PM2 and PM4 become unavailable. In this case, the routes related to the processing modules PM2 and PM4 are eliminated (see the two-dot chain lines in FIG. 8).

When there are two OR transfers and an unavailable processing module PM occurs in each OR transfer, the substrate transfer method is changed to follow a transfer pattern in which all substrates W are transferred to the processing module PM1, and then transferred to the processing module PM3 after the substrate processing. Therefore, similarly to the first transfer pattern, the control device 90 performs control to change two processing modules PM for OR transfer to one processing module PM, thereby changing the supply intervals of the substrates W (see FIG. 4A).

In the third transfer pattern shown in FIG. 9, the substrates W are transferred from the load-lock module LLM1 to the pass module PAS1, and then subjected to the OR transfer to the processing module PM1, the processing module PM3, or the processing module PM4. Further, the third transfer pattern adopt a route in which the substrates W are serially transferred to the processing module PM2 after the substrate processing in the processing modules PM1, PM3, and PM4, and then returned to the load-lock module LLM2 after the substrate processing in the processing module PM2. The third transfer pattern has three processing modules for OR transfer, and it is possible to appropriately cope with the case where the processing modules PM1, PM3, and PM4 become unavailable during the OR transfer. FIG. 9 illustrates an example in which the processing modules PM3 and PM4 become unavailable. In this case, routes related to the processing modules PM3 and PM4 are eliminated (see dashed double-dotted lines in FIG. 9).

When there are three OR transfers and two processing modules PM become unavailable, the substrate transfer method is changed to follow a transfer pattern in which all the substrates W are transferred to the processing module PM1, and then transferred to the processing module PM2 after the substrate processing. Therefore, the control device 90 changes each of the three processing modules PM for OR transfer to one available processing module PM1, and changes the supply intervals of the substrates W according to the number of processing modules PM.

In the fourth transfer pattern shown in FIG. 10, the substrates W are subjected to OR transfer from the load-lock module LLM1 to two processing modules PM1 and PM2, and then subjected to OR transfer to three processing modules PM3, PM5, and PM6 after the substrate processing. Further, the fourth transfer pattern adopts a route in which the substrates W are serially transferred to the processing module PM4 after the substrate processing in the processing modules PM3, PM5, and PM6, and then returned to the load-lock module LLM2 via the pass module PAS1 after the substrate processing in the processing module PM4. In other words, the fourth transfer pattern includes two processing modules PM for OR transfer and three processing modules PM for OR transfer. In this case, it is possible to appropriately cope with the case where one of the processing modules PM1 and PM2 for OR transfer becomes unavailable and some of the three processing modules PM3, PM5, and PM6 becomes unavailable. FIG. 10 illustrates an example in which the processing modules PM1 and PM6 become unavailable. In this case, routes related to the processing modules PM1 and PM6 are eliminated (see dashed double-dotted lines in FIG. 10).

Between the case where one processing module is available in the OR transfer of two processing modules PM and the case where two processing modules are available in the OR transfer of three processing modules PM, the OR transfer of two processing modules has a greater impact on the transfer of the substrates W. In other words, in the OR transfer of two processing modules PM, the ratio of the number of processing modules PM to the number of available processing modules is 1/2. In the OR transfer of three processing modules PM, the ratio of the number of processing modules PM to the number of available processing modules PM is 2/3. In this case, the OR transfer with a smaller ratio has a greater impact on the transfer processing of the substrates W. Therefore, the control device 90 adjusts the supply intervals of the substrates W based on the number of available processing modules PM in the OR transfer of two processing modules with a smaller ratio. If only one processing module is available in the OR transfer of three processing modules PM, the ratio of the OR transfer of three processing modules has a greater impact on the transfer of substrates compared to the ratio of the OR transfer of two processing modules. Therefore, the control device 90 may adjust the supply intervals of the substrates W based on the number of available processing modules PM in the OR transfer of three processing modules with a smaller ratio.

As described above, when there are multiple OR transfers, the control device 90 adjusts the supply intervals of the substrates W based on the OR transfer having a greater impact on the transfer of substrates W. Thus, even when there are multiple OR transfers, it is possible to appropriately transfer the substrates W while suppressing stagnation of the substrates W in the vacuum transfer module TM.

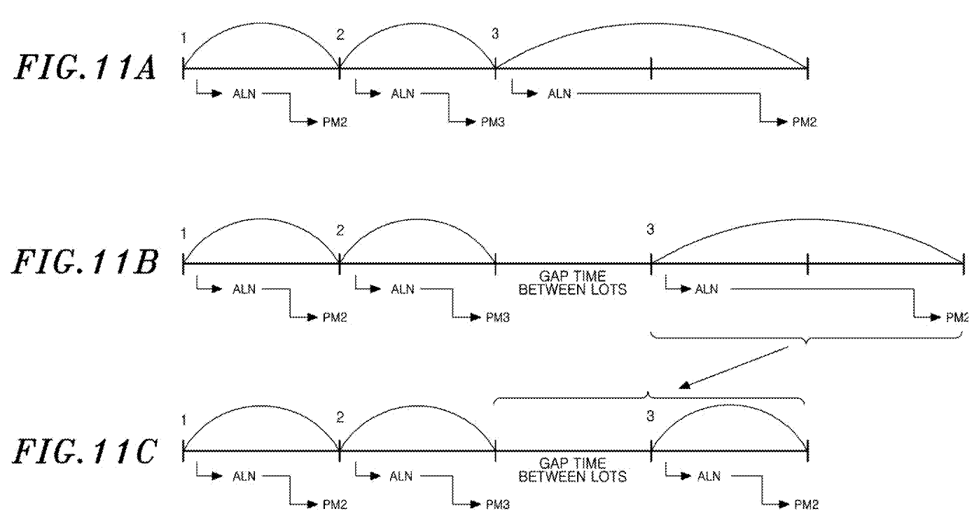

FIG. 11A is a first diagram showing a substrate transfer method according to a modification. FIG. 11B is a diagram showing a substrate transfer method according to a reference example. FIG. 11C is a second diagram showing a transfer method according to a modification. In the substrate processing system 1, time (hereinafter, referred to as “gap time”) may be required to change a transfer target from one lot, which is a group of substrates W, to another lot, which is a group of substrates W. For example, the change between lots may occur when one storage container C is replaced with another storage container C.

When the supply intervals of the substrates W are increased due to an unavailable processing module in the OR transfer as shown in FIG. 11A, if a gap time exists between lots as shown in FIG. 11B, the supply period of the substrates W of a next lot is delayed. Therefore, in the modification, as shown in FIG. 11C, the supply intervals of the substrates W are adjusted in consideration of the gap time between lots. For example, when the supply intervals of the third substrate W are increased, the gap time between lots is subtracted from the supply intervals of the third substrate W. As a result, the supply intervals of the third substrate W are shortened, which makes it possible to efficiently transfer the substrates W.

Alternatively, in order to calculate the number of times of circulation waiting during the gap time between lots, the control device 90 calculates the ratio of the supply intervals of the substrates W to the elapsed time from the previous timing at which the substrate W was unloaded from the aligner device ALN. When the number of times of circulation waiting during the gap time between lots is greater than or equal to the number of unavailable modules in the OR transfer, the control device 90 resets the number of times of circulation waiting to zero. On the other hand, when the number of times of circulation waiting during the gap time between lots is less than the number of unavailable modules in the OR transfer, the control device 90 may perform processing to subtract the number of times of circulation waiting during the gap time between lots from the number of times of circulation waiting. Thus, the substrate processing system 1 can reduce unnecessary waiting during the gap time between lots.

When an unavailable processing module PM is restored during the gap time between lots, the control device 90 may recalculate the ratio of the number of processing modules PM for OR transfer to the number of available processing modules PM, and update the supply intervals of the substrates W.

Further, the substrate processing system 1 according to the embodiment is configured to adjust the supply intervals of the substrates W according to the number of available processing modules PM. However, when the substrate processing period of the processing modules PM is short, for example, it is not required to change the supply intervals of the substrates W even if an unavailable processing module PM occurs. In other words, the substrate processing system 1 may adjust the supply intervals of the substrates W in consideration of the substrate processing period of the processing modules PM, and the like.

### Appendices

The technical ideas and effects of the present disclosure described in the above embodiments will be described below.

### Appendix 1

A substrate processing system comprising: a transfer module including a transfer device configured to transfer substrates; a plurality of processing modules configured to perform substrate processing on the substrates transferred by the transfer module; a substrate standby module configured to temporarily hold the substrates to be transferred to the plurality of processing modules; and a control device configured to create a schedule for the substrates based on the transfer module, the plurality of processing modules, and the substrate standby module, and control transfer of the substrates according to the schedule, wherein the control device acquires information on availability or unavailability of the plurality of processing modules, and adjusts supply intervals of a plurality of substrates based on the number of available processing modules among the acquired plurality of processing modules.

### Appendix 2

The substrate processing system of Appendix 1, wherein the plurality of processing modules include a plurality of processing modules that perform the same substrate processing, the control device is configured to control OR transfer in which the substrates are selectively transferred to the plurality of processing modules that perform the same substrate processing, and adjust the supply intervals of the plurality of substrates based on the number of processing modules for the OR transfer and the number of available processing modules in the OR transfer.

### Appendix 3

The substrate processing system of Appendix 2, wherein the control device increases the supply intervals of the substrates as the number of the available processing modules in the OR transfer decreases relative to the number of processing modules for the OR transfer.

### Appendix 4

The substrate processing system of Appendix 2 or 3, wherein, when the OR transfer is performed multiple times in the plurality of processing modules, the control device adjusts the supply intervals of the substrates based on the OR transfer with a smaller ratio between a ratio of the number of processing modules for first OR transfer to the number of available processing modules in the first OR transfer and a ratio of the number of processing modules for second OR transfer to the number of available processing modules in the second OR transfer.

### Appendix 5

The substrate processing system of any one of Appendices 1 to 4, wherein, when the supply intervals of the substrates are adjusted, the substrates stand by in the substrate standby module.

### Appendix 6

The substrate processing system of Appendix 5, wherein the substrate standby module is an aligner device provided in an atmospheric transfer module that is one of the transfer modules.

### Appendix 7

The substrate processing system of Appendix 5, wherein the substrate standby module is a utility module provided in a vacuum transfer module that is one of the transfer modules, and configured to adjust a temperature of the substrates.

### Appendix 8

A substrate transfer method for a substrate processing system, wherein the substrate processing system includes: a transfer module including a transfer device configured to transfer substrates; a plurality of processing modules configured to perform substrate processing on the substrates transferred by the transfer module; and a substrate standby module configured to temporarily hold the substrates to be transferred to the plurality of processing modules, the substrate transfer method comprising: creating a schedule for the substrates based on the transfer module, the plurality of processing modules, and the substrate standby module; acquiring information on availability or unavailability of the plurality of processing modules; adjusting supply intervals of a plurality of substrates in the schedule based on the number of available processing modules among the acquired plurality of processing modules; and transferring the substrates according to the schedule.

The substrate processing system 1 and the substrate transfer method according to the embodiments disclosed herein are illustrative in all respects and are not restrictive. The embodiments may be variously modified and improved without departing from the scope and spirit of the appended claims. Matters described in the plurality of embodiments above may be adopted in other configurations to the extent that no contradiction arises, and may be combined to the extent that no contradiction arises.

1. A substrate processing system comprising:
a transfer module including a transfer device configured to transfer substrates;
a plurality of processing modules configured to perform substrate processing on the substrates transferred by the transfer module;
a substrate standby module configured to temporarily hold the substrates to be transferred to the plurality of processing modules; and
a control device configured to create a schedule for the substrates based on the transfer module, the plurality of processing modules, and the substrate standby module, and control transfer of the substrates according to the schedule,
wherein the control device acquires information on availability or unavailability of the plurality of processing modules, and
adjusts supply intervals of a plurality of substrates based on the number of available processing modules among the plurality of processing modules indicated by the acquired information.

2. The substrate processing system of claim 1, wherein the plurality of processing modules include a plurality of processing modules configured to perform the same substrate processing, and
the control device is configured to:
control OR transfer in which the substrates are selectively transferred to the plurality of processing modules that perform the same substrate processing; and
adjust the supply intervals of the plurality of substrates based on the number of processing modules for the OR transfer and the number of available processing modules in the OR transfer.

3. The substrate processing system of claim 2, wherein the control device increases the supply intervals of the substrates as the number of the available processing modules in the OR transfer decreases relative to the number of processing modules for the OR transfer.

4. The substrate processing system of claim 2, wherein, when the OR transfer is performed multiple times in the plurality of processing modules, the control device adjusts the supply intervals of the substrates based on the OR transfer with a smaller ratio between a ratio of the number of processing modules for first OR transfer to the number of available processing modules in the first OR transfer and a ratio of the number of processing modules for second OR transfer to the number of available processing modules in the second OR transfer.

5. The substrate processing system of claim 1, wherein, when the supply intervals of the substrates are adjusted, the substrates stand by in the substrate standby module.

6. The substrate processing system of claim 2, wherein, when the supply intervals of the substrates are adjusted, the substrates stand by in the substrate standby module.

7. The substrate processing system of claim 3, wherein, when the supply intervals of the substrates are adjusted, the substrates stand by in the substrate standby module.

8. The substrate processing system of claim 4, wherein, when the supply intervals of the substrates are adjusted, the substrates stand by in the substrate standby module.

9. The substrate processing system of claim 5, wherein the substrate standby module is an aligner device provided in an atmospheric transfer module that is one of the transfer modules.

10. The substrate processing system of claim 6, wherein the substrate standby module is an aligner device provided in an atmospheric transfer module that is one of the transfer modules.

11. The substrate processing system of claim 7, wherein the substrate standby module is an aligner device provided in an atmospheric transfer module that is one of the transfer modules.

12. The substrate processing system of claim 8, wherein the substrate standby module is an aligner device provided in an atmospheric transfer module that is one of the transfer modules.

13. The substrate processing system of claim 5, wherein the substrate standby module is a utility module provided in a vacuum transfer module that is one of the transfer modules, and configured to adjust a temperature of the substrates.

14. The substrate processing system of claim 6, wherein the substrate standby module is a utility module provided in a vacuum transfer module that is one of the transfer modules, and configured to adjust a temperature of the substrates.

15. The substrate processing system of claim 7, wherein the substrate standby module is a utility module provided in a vacuum transfer module that is one of the transfer modules, and configured to adjust a temperature of the substrates.

16. The substrate processing system of claim 8, wherein the substrate standby module is a utility module provided in a vacuum transfer module that is one of the transfer modules, and configured to adjust a temperature of the substrates.

17. A substrate transfer method for a substrate processing system, wherein the substrate processing system includes:
a transfer module including a transfer device configured to transfer substrates;
a plurality of processing modules configured to perform substrate processing on the substrates transferred by the transfer module; and
a substrate standby module configured to temporarily hold the substrates to be transferred to the plurality of processing modules,
the substrate transfer method comprising:
creating a schedule for the substrates based on the transfer module, the plurality of processing modules, and the substrate standby module;
acquiring information on availability or unavailability of the plurality of processing modules;
adjusting supply intervals of a plurality of substrates in the schedule based on the number of available processing modules among the plurality of processing modules indicated by the acquired information; and
transferring the substrates according to the schedule.
